(19) United States
(12) Patent Application Publication
(10) Pub. No.: US 2025/0266271 A1
(43) Pub. Date: Aug. 21, 2025

(54) PROCESSING LIQUID SUPPLY SYSTEM, PROCESSING LIQUID SUPPLY METHOD, AND RECORDING MEDIUM

(71) Applicant: Tokyo Electron Limited, Tokyo (JP)

(72) Inventors: Hisashi MORITA, Koshi City (JP); Yuji KIMURA, Koshi City (JP); Yusuke YAMAMOTO, Koshi City (JP)

(73) Assignee: Tokyo Electron Limited, Tokyo (JP)

(21) Appl. No.: 19/054,074

(22) Filed: Feb. 14, 2025

(30) Foreign Application Priority Data
Feb. 15, 2024 (JP) 2024-021321

(51) Int. Cl. H01L 21/67

(52) U.S. Cl. CPC H01L 21/67086; H01L 21/67248; H01L 21/67253

(57) ABSTRACT

A processing liquid supply system includes a processing liquid supply for supplying a processing liquid into a processing tub in which a substrate is immersed to be processed; a circulation path for allowing the processing liquid to flow out from the processing tub and return back into the processing tub; a pump and a flowmeter provided in the circulation path; and a controller. The controller performs: storing the processing liquid in the processing tub; filling the circulation path with the processing liquid; circulating the processing liquid through the circulation path by operating, after the filling of the circulation path, the pump such that the processing liquid reaches a predetermined initial set flow rate; and operating, after a timepoint when a measurement value of the flowmeter has reached the initial set flow rate, the pump to achieve a predetermined processing set flow rate at which the substrate is processed.

### CROSS-REFERENCE TO RELATED APPLICATION

This application claims the benefit of Japanese Patent Application No. 2024-021321 filed on Feb. 15, 2024, the entire disclosure of which are incorporated herein by reference.

### TECHNICAL FIELD

The various aspects and embodiments described herein pertain generally to a processing liquid supply system, a processing liquid supply method, and a recording medium.

### BACKGROUND

Conventionally, there is known a substrate processing apparatus configured to circulate a processing liquid through a processing tub for processing a substrate to perform various types of processes on the substrate immersed in the processing tub (see Patent Document 1).

Patent Document 1: Japanese Patent Laid-open Publication No. 2021-022707.

### SUMMARY

In one or more embodiments, a processing liquid supply system includes a processing liquid supply, a circulation path, a pump, a flowmeter, and a controller. The processing liquid supply is configured to supply a processing liquid into a processing tub in which a substrate is immersed to be processed. The circulation path is configured to allow the processing liquid to flow out from the processing tub and return back into the processing tub. The pump and the flowmeter are provided in the circulation path. The controller is configured to control each component. The controller performs: storing the processing liquid in the processing tub by supplying the processing liquid from the processing liquid supply; filling the circulation path with the processing liquid by operating the pump to allow the processing liquid to flow through the circulation path; circulating the processing liquid through the circulation path by operating, after the filling of the circulation path, the pump such that the processing liquid flowing through the circulation path reaches a predetermined initial set flow rate; and operating, after a timepoint when a measurement value of the flowmeter has reached the initial set flow rate, the pump to achieve a predetermined processing set flow rate at which the substrate is processed.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a block diagram illustrating a configuration example of a substrate processing apparatus according to one or more embodiments.

FIG. 2 is a diagram illustrating a configuration example of a liquid processing device according to one or more embodiments.

FIG. 3 is a diagram illustrating a configuration example of a processing liquid supply system according to one or more embodiments.

FIG. 4 is a timing chart illustrating an example sequence of a startup processing performed by the substrate processing apparatus according to one or more embodiments.

FIG. 5 is a timing chart illustrating an example sequence of a circulation processing and a temperature control processing performed by the processing liquid supply system according to one or more embodiments.

FIG. 6 is a timing chart illustrating an example sequence of the circulation processing and the temperature control processing performed by the processing liquid supply system according to one or more embodiments.

FIG. 7 is a diagram illustrating a configuration example of a processing liquid supply system according to a first modification example of one or more embodiments.

FIG. 8 is a diagram illustrating a configuration example of a processing liquid supply system according to a second modification example of one or more embodiments.

FIG. 9 is a diagram illustrating an example sequence of a control processing performed by the processing liquid supply system according to one or more embodiments.

FIG. 10 is a diagram illustrating another example sequence of the control processing performed by the processing liquid supply system according to one or more embodiments.

FIG. 11 is a diagram illustrating still another example sequence of the control processing performed by the processing liquid supply system according to one or more embodiments.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the one or more embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a processing liquid supply system, a processing liquid supply method, and a recording medium according to the present disclosure will be described in detail with reference to the accompanying drawings. However, the present disclosure is not limited by the exemplary embodiments to be described below. Also, it should be noted that the drawings are schematic and relations in sizes of individual components and ratios of the individual components may sometimes be different from actual values. Even between the drawings, there may exist parts having different dimensional relationships or different ratios.

Conventionally, there is known a substrate processing apparatus in which a processing liquid is circulated through a processing tub for processing a substrate to perform various types of processes on the substrate immersed in the processing tub. In this conventional technique, however, if an output of a pump alone is increased to increase a flow rate of the processing liquid sent from a circulation path back into the processing tub, there is a risk of malfunctioning of the pump.

In this regard, to overcome the aforementioned problem, there is a demand for a technique capable of increasing the flow rate of the processing liquid sent from the circulation path back into the processing tub without causing any problem in the operation of the pump.

### Configuration of Substrate Processing Apparatus

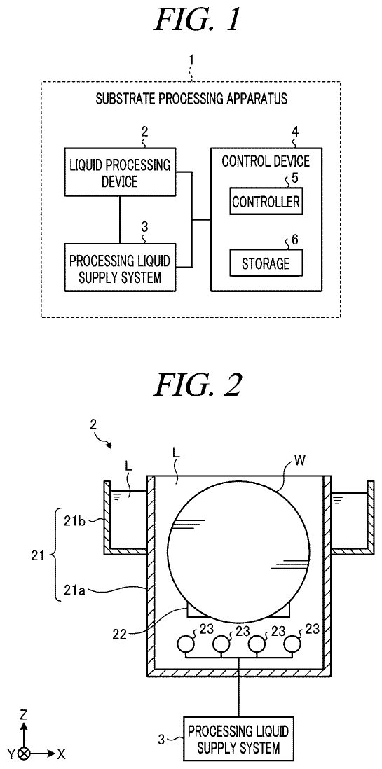

First, a configuration of a substrate processing apparatus 1 including a processing liquid supply system 3 according to the present disclosure will be explained with reference to FIG. 1. FIG. 1 is a block diagram illustrating a configuration example of the substrate processing apparatus 1 according to one or more embodiments.

As shown in FIG. 1, the substrate processing apparatus 1 according to the exemplary embodiment is equipped with a liquid processing device 2, a processing liquid supply system 3, and a control device 4.

The liquid processing device 2 is configured to process a substrate (hereinafter, also referred to as “wafer”) such as a semiconductor wafer by using a processing liquid L (see FIG. 2).

The processing liquid L according to the exemplary embodiment contains, by way of example, a phosphoric acid (H3PO4) aqueous solution. In the present disclosure, the phosphoric acid aqueous solution is also simply referred to as “phosphoric acid”. Further, the processing liquid L according to the exemplary embodiment may also include a silicic acid compound. This silicic acid compound can be added to the phosphoric acid aqueous solution, for example, with a solution in which colloidal silicon is dispersed.

In addition, in the present disclosure, the processing liquid L is not limited to the one containing the phosphoric acid, and any of various types of processing liquids for liquid-processing the wafer W may be employed.

The processing liquid supply system 3 is configured to supply the above-described processing liquid L to the liquid processing device 2. A configuration example of the processing liquid supply system 3 will be described later.

The control device 4 controls the liquid processing device 2 and the processing liquid supply system 3. The control device 4 is, for example, a computer, and includes a controller 5 and a storage 6. The storage 6 stores therein programs for controlling various types of processes performed in the substrate processing apparatus 1. The controller 5 controls operations of the liquid processing device 2 and the processing liquid supply system 3 by reading and executing the programs stored in the storage 6. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASICT.

Further, these programs may be recorded on a computer-readable recording medium and installed from the recording medium into the storage 6 of the control device 4. The computer-readable recording medium may be, by way of non-limiting example, a hard disk (HD), a flexible disk (FD), a compact disk (CD), a magnet optical disk (MO), a memory card, or the like.

The substrate processing apparatus 1 may be equipped with a plurality of liquid processing devices 2. In this case, the substrate processing apparatus 1 may include a plurality of processing liquid supply systems 3 respectively corresponding to the plurality of liquid processing devices 2, or may include one processing liquid supply system 3 corresponding to all the plurality of liquid processing devices 2.

### Configuration of Liquid Processing Device

Now, a configuration example of the liquid processing device 2 will be described with reference to FIG. 2. FIG. 2 is a diagram illustrating an example of the configuration of the liquid processing device 2 according to the exemplary embodiment.

The liquid processing device 2 shown in FIG. 2 is a batch type processing device configured to process a multiple number of wafers W (only one is shown in FIG. 2) all at once. As depicted in FIG. 2, the liquid processing device 2 is equipped with a processing tub 21, a holder 22, and a plurality of (here, four) dischargers 23. Here, the number of the dischargers 23 included in the liquid processing device 2 is not limited to four.

The processing tub 21 includes an inner tub 21a and an outer tub 21b. The inner tub 21a is a box-shaped tub with an open top, and stores the processing liquid L therein. A lot composed of a plurality of wafers W is immersed in the inner tub 21a. The outer tub 21b is disposed around the inner tub 21a. The outer tub 21b also has an open top. The processing liquid L that has overflown from the inner tub 21a is introduced into the outer tub 21b.

The holder 22 is configured to hold the multiple number of wafers W forming the lot in a vertical posture. The holder 22 has an elevating mechanism (not shown) configured to move the wafers W held thereby up and down, and serves to lower the lot from above the inner tub 21a in the processing tub 21 to immerse it in the inner tub 21a, or raise the lot immersed in the inner tub 21a to take it out from the processing tub 21.

The plurality of dischargers 23 are disposed inside the inner tub 21a, specifically, in the vicinity of a bottom of the inner tub 21a. The dischargers 23 are connected to the processing liquid supply system 3, and discharge the processing liquid L supplied from the processing liquid supply system 3 into the inner tub 21a.

The liquid processing device 2 holds the lot with the holder 22, and immerses the lot held thereby in the processing liquid L stored in the inner tub 21a. As a result, the multiple number of wafers W are processed by the processing liquid L.

For example, in the exemplary embodiment, among a silicon nitride film and a silicon oxide film formed on the wafer W, the silicon nitride film is selectively etched by the phosphoric acid aqueous solution, which is the processing liquid L.

### <Configuration of processing liquid supply system>

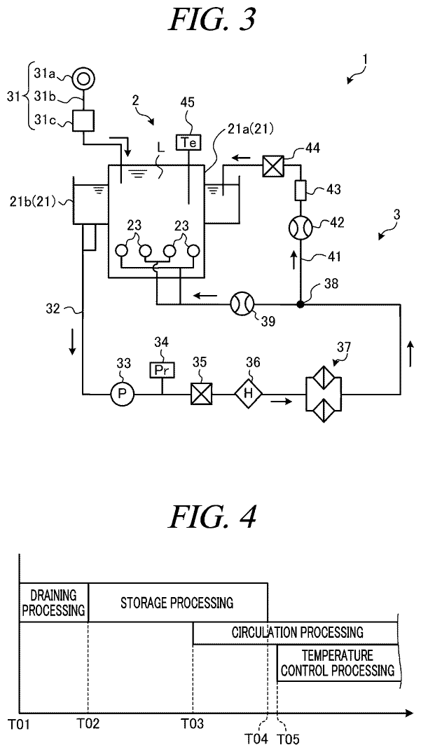

Now, a configuration example of the processing liquid supply system 3 will be described with reference to FIG. 3. FIG. 3 is a diagram illustrating a configuration example of the processing liquid supply system 3 according to one or more embodiments.

As depicted in FIG. 3, the processing liquid supply system 3 includes a processing liquid supply 31 and a circulation path 32. The processing liquid supply 31 supplies the processing liquid L to the processing tub 21. The processing liquid supply 31 supplies unused processing liquid L to the inner tub 21a of the processing tub 21, for example.

The processing liquid supply 31 has a source 31a, a supply path 31b, and a flow rate controller 31c. The source 31a is, for example, a tank that stores the processing liquid L therein. The supply path 31b connects the source 31a to the inner tub 21a, allowing the processing liquid L to be supplied from the source 31a to the inner tub 21a. Also, the supply path 31b may be connected to the outer tub 21b.

The flow rate controller 31c is provided in the supply path 31b, and serves to adjust the amount of the processing liquid L supplied to the processing tub 21. The flow rate controller 31c is composed of, by way of example, an opening/closing valve, a flow control valve, a flowmeter, and so forth.

The circulation path 32 is connected to the liquid processing device 2 to supply the processing liquid L to the liquid processing device 2. The circulation path 32 is a circulation line through which the processing liquid L flowing out from the processing tub 21 is returned back into the processing tub 21.

Specifically, one end of the circulation path 32 is connected to multiple positions (two positions in FIG. 3) at a bottom of the outer tub 21b, and the other end of the circulation path 32 is connected to the plurality of dischargers 23 located inside the inner tub 21a. In the processing liquid supply system 3, the processing liquid L sent from the outer tub 21b into the circulation path 32 passes through the circulation path 32 and is then supplied from the dischargers 23 into the inner tub 21a.

Furthermore, the processing liquid L supplied from the dischargers 23 into the inner tub 21a overflows from the inner tub 21a into the outer tub 21b. In this way, the circulation path 32 allows the processing liquid L to be circulated between the inner tub 21a and the outer tub 21b.

The circulation path 32 is provided with a pump 33, a pressure gauge 34, a check valve 35, a heater 36, a filter 37, a branching portion 38, and a flowmeter 39 in this order from the upstream side with respect to the processing tub 21.

The pump 33 forms a circulating flow of the processing liquid L that comes out from the processing tub 21, passes through the circulation path 32, and returns back into the processing tub 21. The pump 33 is, by way of non-limiting example, a magnetic levitation pump configured to force-feed the processing liquid L as a rotator thereof is rotated in the processing liquid L while being magnetically levitated. However, the pump 33 of the present disclosure is not limited to the magnetic levitation pump, and may be, by way of example, a diaphragm pump or the like.

Meanwhile, since the magnetic levitation pump, which has higher liquid feeding capacity than other types of pumps, is used for the pump 33, the feed flow rate of the processing liquid L returned from the circulation path 32 into the processing tub 21 can be increased.

The pressure gauge 34 measures the pressure of the processing liquid L flowing through the circulation path 32. A measurement value of the pressure of the processing liquid L measured by the pressure gauge 34 is outputted to the controller 5 (see FIG. 1). The check valve 35 suppresses a backflow of the processing liquid L flowing through the circulation path 32. The check valve 35 is, by way of non-limiting example, an air-operated valve.

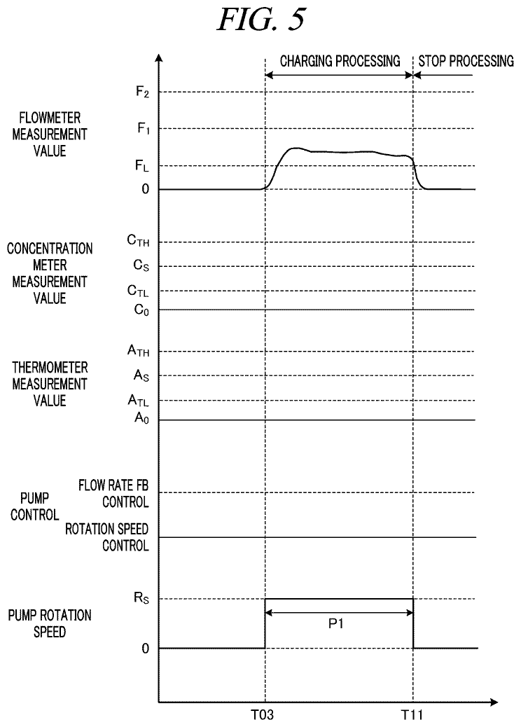

The heater 36 heats the processing liquid L flowing through the circulation path 32. In this exemplary embodiment, by heating the processing liquid L with this heater 36, the processing liquid L stored in the processing tub 21 is heated up to a processing set temperature AS (see FIG. 5) (for example, about 160° C. to 170° C.) required for processing the wafer W.

The filter 37 is configured to remove contaminants such as particles contained in the processing liquid L flowing through the circulation path 32. The filter 37 may include a plurality of filter modules arranged in parallel.

The number of the filter modules belonging to the single filter 37 may be decided in consideration of filtration ability required for the filter 37, a pressure drop allowed in the filter 37, and so forth. In the present disclosure, the filter 37 is composed of two filter modules arranged in parallel, as illustrated in FIG. 3.

A branch path 41 leading to the outer tub 21b of the processing tub 21 is branched off from the branching portion 38. The flowmeter 39 measures the flow rate of the processing liquid L flowing through the circulation path 32. A measurement value of the flow rate of the processing liquid L measured by the flowmeter 39 is outputted to the controller 5.

The branch path 41 is a flow path for sampling the concentration of the processing liquid L flowing through the circulation path 32. A flowmeter 42, a concentration meter 43, and a valve 44 are provided in this branch path 41 in this order from the upstream side with respect to the branching portion 38.

The flowmeter 42 measures the flow rate of the processing liquid L flowing through the branch path 41. A measurement value of the flow rate of the processing liquid L measured by the flowmeter 42 is outputted to the controller 5.

The concentration meter 43 measures the concentration of the processing liquid L flowing through the branch path 41, which reflects the concentration of the processing liquid L flowing through the circulation path 32. The concentration meter 43 measures, for example, a phosphoric acid concentration of the processing liquid L flowing through the branch path 41. A measurement value of the concentration of the processing liquid L measured by the concentration meter 43 is outputted to the controller 5. The valve 44 controls whether or not the processing liquid L is to be supplied from the branching portion 38 to the outer tub 21b.

The processing liquid supply system 3 is also equipped with a thermometer 45. The thermometer 45 measures the temperature of the processing liquid L flowing through the circulation path 32 by measuring the temperature of the processing liquid L stored in the processing tub 21. The thermometer 45 measures the temperature of the processing liquid L stored in the inner tub 21a, for example. A measurement value of the temperature of the processing liquid L measured by the thermometer 45 is outputted to the controller 5.

Furthermore, the thermometer 45 of the present disclosure is not limited to measuring the temperature of the processing liquid L stored in the inner tub 21a, but may be configured to measure the temperature of the processing liquid L stored in the outer tub 21b or to measure the temperature of the processing liquid L flowing through the circulation path 32.

### Details of Startup Processing

Now, details of a startup processing of the substrate processing apparatus 1 according to one or more embodiments will be described with reference to FIG. 4 to FIG. 6. FIG. 4 is a timing chart showing an example sequence of the startup processing performed by the substrate processing apparatus 1 according to the embodiment.

First, the controller 5 (see FIG. 1) performs a draining processing of draining all the processing liquid L used (see FIG. 3) from the inner tub 21a (see FIG. 3) and the outer tub 21b (see FIG. 3) of the processing tub 21 (see FIG. 3) from time T01.

Next, from time T02 when the draining processing is completed, the controller 5 performs a storage processing of replenishing the inner tub 21a and the outer tub 21b of the processing tub 21 with the processing liquid L unused. Specifically, the controller 5 first supplies the processing liquid L from the processing liquid supply 31 (see FIG. 3) to the inner tub 21a, filling the inner tub 21a with the processing liquid L.

Next, the controller 5 further supplies the processing liquid L from the processing liquid supply 31 into the inner tub 21a, thus allowing the processing liquid L overflowing from the inner tub 21a to be supplied into the outer tub 21b. Then, at time T04 when the liquid level of the processing liquid L supplied to the outer tub 21b reaches a predetermined second height, the controller 5 ends the storage processing.

The controller 5 performs a circulation processing of circulating the processing liquid L through the circulation path 32 (see FIG. 3) from time T03 when the liquid level of the processing liquid L supplied into the outer tub 21b reaches a preset first height, which is lower than the second height. During this circulation processing, from time T05 when the processing liquid L meets a condition to be described below, the controller 5 performs a temperature control processing of adjusting the temperature of the processing liquid L to a preset processing set temperature AS (see FIG. 5).

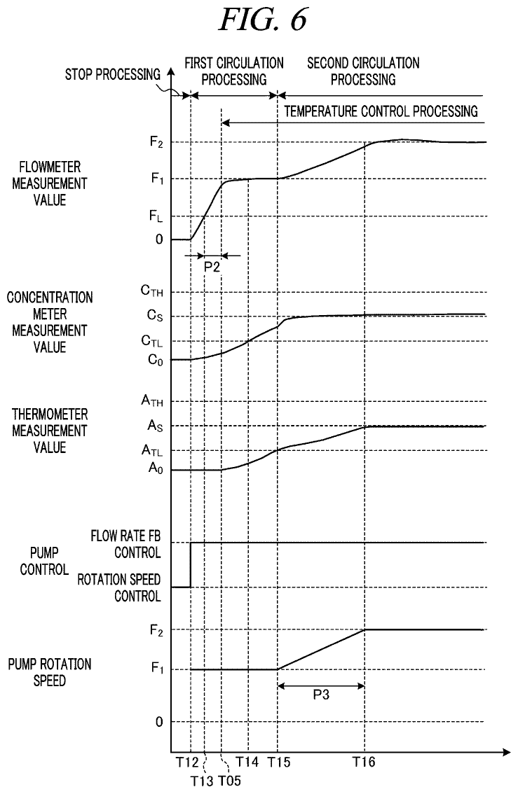

Details of these circulation processing and temperature control processing will be discussed with reference to FIG. 5 and FIG. 6. FIG. 5 and FIG. 6 are timing charts illustrating example sequences of the circulation processing and the temperature control processing performed by the processing liquid supply system 3 according to one or more embodiments.

As shown in FIG. 5, as an initial process in the circulation processing, the controller 5 (see FIG. 1) operates the pump 33 (see FIG. 3) from the aforementioned time T03 to allow the processing liquid L (see FIG. 3) to flow through the circulation path 32 (see FIG. 3), thereby performing a charging processing of filling the circulation path 32 with the processing liquid L.

In addition, when a magnetic levitation pump is used for the pump 33, there are two types of operation modes for the pump 33: a flow rate feedback control (referred to as “flow rate FB control” in the accompanying drawings) and a rotation speed control.

In flow rate feedback control, the rotation speed of the rotator inside the pump 33 is automatically controlled so that a flow rate measurement value of the processing liquid L measured by the flowmeter 39 (see FIG. 3) reaches a designated flow rate.

By way of example, in the flow rate feedback control, if the flow rate measurement value of the processing liquid L is lower than the designated flow rate, the pump 33 increases the rotation speed of the rotator. On the other hand, in the flow rate feedback control, if the flow rate measurement value of the processing liquid L is higher than the designated flow rate, the pump 33 reduces the rotation speed of the rotator.

In the rotation speed control, the rotation speed of the rotator of the pump 33 is controlled to a specified rotation speed.

In the charging processing according to one or more embodiments, the controller 5 operates the pump 33 under the rotation speed control, as shown in FIG. 5. Furthermore, in the charging processing, the controller 5 operates the pump 33 at a specified rotation speed RS.

In this way, by operating the pump 33 under the rotation speed control during the charging processing, the pump 33 can be operated stably even when the circulation path 32 is not filled with the processing liquid L, the measurement value of the flowmeter 39 is unstable, and the flow rate feedback control is difficult to perform. Therefore, according to one or more embodiments, the circulation path 32 can be stably filled with the processing liquid L.

In addition, in one or more embodiments, during the charging processing, the pump 33 needs to be operated at the rotation speed RS at which the measurement value of the flowmeter 39 becomes equal to or greater than a minimum circulation flow rate FL and cavitation does not occur inside the pump 33. This allows the circulation path 32 to be stably filled with the processing liquid L.

Furthermore, as shown in FIG. 5, the charging processing according to one or more embodiments needs to be carried out for a predetermined period P1 from the time T03 as long as the circulation path 32 can be sufficiently filled with processing liquid L. This allows the circulation path 32 to be filled with processing liquid L more reliably.

Also, in one or more embodiments, a concentration measurement value of the processing liquid L measured by the concentration meter 43 (see FIG. 3) before and after the start of the charging processing is stabilized at an initial concentration C0 supplied from the processing liquid supply 31 (see FIG. 3), as shown in FIG. 5.

Likewise, a temperature measurement value of the processing liquid L measured by the thermometer 45 (see FIG. 3) before and after the start of the charging processing is stabilized at an initial temperature A0 supplied from the processing liquid supply 31.

Following the charging processing described so far, the controller 5 performs a stop processing of stopping the pump 33 (that is, setting the rotation speed of the rotator to zero) from time T11 to stop the circulation of the processing liquid L in the circulation path 32 in the circulation processing according to one or more embodiments. The time T11 is the time upon the lapse of the predetermined period P1 from the time T03. As a result, the measurement value of the flowmeter 39 becomes zero, as shown in FIG. 5.

Thereafter, in the circulation processing according to one or more embodiments, the controller 5 performs, from time T12, a first circulation processing of circulating the processing liquid L so that the processing liquid L (see FIG. 3) flowing through the circulation path 32 (see FIG. 3) reaches a predetermined initial set flow rate F1, as shown in FIG. 6. Here, the time T12 is the time upon the lapse of a predetermined period from the time T11 (see FIG. 5). Further, the initial set flow rate F1 is a value larger than the minimum circulation flow rate FL.

To perform this first circulation processing, the controller 5 (see FIG. 1) switches the operation mode of the pump 33 (see FIG. 3) from the rotation speed control to the flow rate feedback control.

In the first circulation processing, the controller 5 operates the pump 33, while setting the set flow rate of the processing liquid L in the circulation path 32 to the initial set flow rate F1. As a result, the measurement value of the flowmeter 39 gradually increases from zero, as shown in FIG. 6.

Furthermore, in the present exemplary embodiment, from the time T05 after the start of the first circulation processing, the controller 5 operates the heater 36 (see FIG. 3) to perform the temperature control processing for the processing liquid L. This time T05 is the time upon the lapse of a predetermined period P2 from time T13 when the measurement value of the flowmeter 39 reaches the minimum circulation flow rate FL.

In this way, instead of operating the heater 36 immediately after the minimum circulation flow rate FL is reached, by allowing a margin of the period P2 before operating the heater 36, it is possible to operate the heater 36 after securing a sufficient circulation flow rate in the circulation path 32.

Therefore, according to one or more embodiments, it is possible to suppress a problem that might be caused by operating the heater 36 when the flow rate in the circulation path 32 is not sufficient.

In one or more embodiments, the measurement value of the thermometer 45 gradually rises from the temperature A0 from the time T05 when the temperature control processing is begun. Further, in one or more embodiments, as the processing liquid L overflows from the inner tub 21a into the outer tub 21b and the temperature of the processing liquid L increases, the moisture in the processing liquid L evaporates from the processing tub 21, so that the measurement value of the concentration meter 43 gradually rises from the concentration C0.

Then, in the present exemplary embodiment, after a timepoint (time T14 in the example of FIG. 6) when the measurement value of the flowmeter 39 reaches the initial set flow rate F1, the controller 5 performs a second circulation processing in which the pump 33 is operated so that the flow rate in the circulation path 32 reaches a preset processing set flow rate F2 for processing the wafer W. This processing set flow rate F2 is a value larger than the initial set flow rate F1.

That is, in the circulation processing according to one or more embodiments, the pump 33 is operated so that the flow rate in the circulation path 32 reaches the processing set flow rate F2 after the flow rate in the circulation path 32 is first stabilized to the initial set flow rate F1.

As a result, as compared to a case where the pump 33 is operated so that the flow rate in the circulation path 32 increases from zero to the processing set flow rate F2 at once, it is possible to suppress cavitation from occurring in the pump 33 even if the flow rate of the processing liquid L is increased.

Therefore, according to one or more embodiments, the flow rate of the processing liquid L sent from the circulation path 32 back into the processing tub 21 can be increased.

Furthermore, in the present exemplary embodiment, the controller 5 may start the second circulation processing when the measurement value of the flowmeter 39 becomes the initial set flow rate F1 and the measurement value of the concentration meter 43 reaches a predetermined concentration range.

By way of example, in one or more embodiments, the second circulation processing may be started when the measurement value of the concentration meter 43 falls between a preset lower limit concentration CTL, which is lower than a processing set concentration CS for processing the wafer W, and a preset upper limit concentration CTH, which is higher than the processing set concentration CS.

This allows the pump 33 to be operated to achieve the processing set flow rate F2 after the viscosity of the processing liquid L is brought close to a viscosity level for processing of the wafer W. Thus, even if the flow rate of the processing liquid L is increased, occurrence of cavitation inside the pump 33 can be further suppressed.

Therefore, according to the present exemplary embodiment, the flow rate of the processing liquid L sent from the circulation path 32 back into the processing tub 21 can be stably increased.

In addition, in the present exemplary embodiment, the controller 5 may start the second circulation processing when the measurement value of the flowmeter 39 reaches the initial set flow rate F1 and the measurement value of the thermometer 45 falls within a predetermined temperature range.

By way of example, in one or more embodiments, the second circulation processing may be started when the measurement value of the thermometer 45 falls between a preset lower limit temperature ATL, which is lower than the processing set temperature AS for processing the wafer W, and a preset upper limit temperature ATH, which is higher than the processing set temperature AS.

This allows the pump 33 to be operated to achieve the processing set flow rate F2 after the viscosity of the processing liquid L is made closer to the viscosity level for processing the wafer W. Thus, even if the flow rate of the processing liquid L is increased, occurrence of cavitation inside the pump 33 can be further suppressed.

Therefore, according to the present exemplary embodiment, the flow rate of the processing liquid L sent from the circulation path 32 back into the processing tub 21 can be stably increased.

Furthermore, in one or more embodiments, the second circulation processing may be started from time T15 when the measurement value of the flowmeter 39 has reached the initial set flow rate F1, the measurement value of the concentration meter 43 has reached the predetermined concentration range, and the measurement value of the thermometer 45 has reached the predetermined temperature range.

This allows the pump 33 to be operated to achieve the processing set flow rate F2 after the viscosity of the processing liquid L is made further closer to the viscosity level for processing the wafer W. Thus, even if the flow rate of the processing liquid L is increased, occurrence of cavitation inside the pump 33 can be further suppressed.

Therefore, according to the present exemplary embodiment, the flow rate of the processing liquid L sent from the circulation path 32 back into the processing tub 21 can be stably increased.

In the example of FIG. 6, the controller 5 starts the second circulation processing from the aforementioned time T15, and gradually increases the set flow rate of the pump 33 from the time T15 to time T16. The time T16 is the time upon the lapse of a predetermined period P3 from the time T15.

Then, the controller 5 sets the set flow rate of the pump 33 to the processing set flow rate F2 for processing the wafer W at the time T16. As a result, the measurement value of the flowmeter 39 becomes the processing set flow rate F2 for processing the wafer W, the measurement value of the concentration meter 43 becomes the processing set concentration CS for processing the wafer W, and the measurement value of the thermometer 45 becomes the processing set temperature AS for processing the wafer W. Then, the series of processes of the startup processing are completed.

In the present exemplary embodiment, by gradually increasing the set flow rate of the pump 33 from the time T15 to the time T16, a rapid change in the flow rate in the circulation path 32 can be suppressed. Thus, according to the present exemplary embodiment, it is possible to suppress occurrence of cavitation inside the pump 33.

### First Modification Example

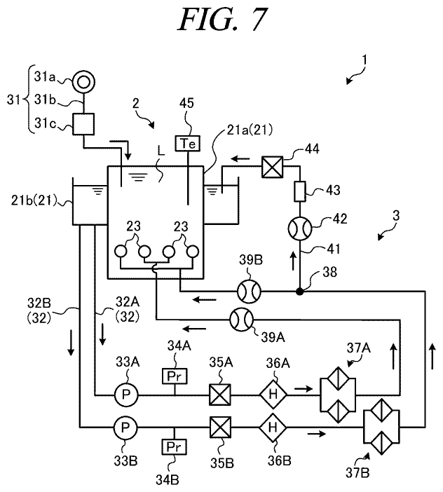

Now, the processing liquid supply system 3 according to a first modification example of one or more embodiments and a startup processing using this processing liquid supply system 3 will be explained with reference to FIG. 7 in addition to FIG. 5 and FIG. 6 described above. FIG. 7 is a diagram illustrating a configuration example of the processing liquid supply system 3 according to the first modification example of one or more embodiments.

The first modification example shown in FIG. 7 is different from the above-described exemplary embodiment in the configuration of the circulation path 32. Specifically, in this first modification example, multiple circulation paths 32 (two in the example of FIG. 7) are provided for the single processing tub 21. With this configuration, it is possible to increase the flow rate of the processing liquid L returned back into the processing tub 21 from the circulation path 32, as compared to the case where only one circulation path 32 is provided for the single processing tub 21.

The circulation path 32 according to the first modification example includes circulation paths 32A and 32B. Each of the circulation paths 32A and 32B is connected to the liquid processing device 2 to supply the processing liquid L to the liquid processing device 2. Each of the circulation paths 32A and 32B is a circulation line through which the processing liquid L flows out from the processing tub 21 and returns back into the processing tub 21.

To elaborate, one end of each of the circulation paths 32A and 32B is connected to the bottom of the outer tub 21b, and the other end of each of the circulation paths 32A and 32B is connected to the plurality of dischargers 23 located inside the inner tub 21a.

In the processing liquid supply system 3, the processing liquid L sent from the outer tub 21b to the circulation paths 32A and 32B passes through the circulation paths 32A and 32B and is then supplied into the inner tub 21a from the dischargers 23.

Furthermore, the processing liquid L supplied from the dischargers 23 to the inner tub 21a overflows from the inner tub 21a into the outer tub 21b. In this way, the circulation paths 32A and 32B circulate the processing liquid L between the inner tub 21a and the outer tub 21b.

The circulation path 32A is provided with a pump 33A, a pressure gauge 34A, a check valve 35A, a heater 36A, a filter 37A, and a flowmeter 39A in this order from the upstream side with respect to the processing tub 21.

The pump 33A forms a circulation flow of the processing liquid L that comes out from the processing tub 21, passes through the circulation path 32A, and then returns back into the processing tub 21. The pump 33A is, for example, a magnetic levitation pump. However, it should be noted that the pump 33A of the present disclosure is not limited to the magnetic levitation pump, and may be a diaphragm pump, or the like.

The pressure gauge 34A measures the pressure of the processing liquid L flowing through the circulation path 32A. A measurement value of the pressure of the processing liquid L measured by the pressure gauge 34A is outputted to the controller 5 (see FIG. 1). The check valve 35A suppresses a backflow of the processing liquid L flowing through the circulation path 32A. The check valve 35A is, by way of non-limiting example, an air-operated valve.

The heater 36A heats the processing liquid L flowing through the circulation path 32A. In the first modification example, by heating the processing liquid L with the heater 36A, the processing liquid L stored in the processing tub 21 is heated up to the processing set temperature AS (see FIG. 5) required for processing the wafer W.

The filter 37A removes contaminants such as particles contained in the processing liquid L flowing through the circulation path 32A. The filter 37A may include multiple filter modules arranged in parallel.

The flowmeter 39A measures the flow rate of the processing liquid L flowing through the circulation path 32A. A measurement value of the flow rate of the processing liquid L measured by the flowmeter 39A is outputted to the controller 5.

The circulation path 32B is provided with a pump 33B, a pressure gauge 34B, a check valve 35B, a heater 36B, a filter 37B, the branching portion 38, and a flowmeter 39B in this order from the upstream side with respect to the processing tub 21.

The pump 33B forms a circulation flow of the processing liquid L that flows out from the processing tub 21, passes through the circulation path 32B, and then returns back into the processing tub 21. The pump 33B is, for example, a magnetic levitation pump configured to force-feed the processing liquid L as a rotator thereof is rotated in the processing liquid L while being magnetically levitated. However, the pump 33B of the present disclosure is not limited to the magnetic levitation pump, and may be a diaphragm pump or the like.

The pressure gauge 34B measures the pressure of the processing liquid L flowing through the circulation path 32B. A measurement value of the pressure of the processing liquid L measured by the pressure gauge 34B is outputted to the controller 5. The check valve 35B suppresses a backflow of the processing liquid L flowing through the circulation path 32B. The check valve 35B is, by way of non-limiting example, an air-operated valve.

The heater 36B heats the processing liquid L flowing through the circulation path 32B. In the first modification example, by heating the processing liquid L with this heater 36B, the processing liquid L stored in the processing tub 21 is heated up to the processing set temperature AS required for processing the wafer W.

The filter 37B removes contaminants such as particles contained in the processing liquid L flowing through the circulation path 32B. The filter 37B may include multiple filter modules arranged in parallel.

The branch path 41 that leads to the outer tub 21b of the processing tub 21 is branched off from the branching portion 38. The flowmeter 39B measures the flow rate of the processing liquid L flowing through the circulation path 32B. A measurement value of the flow rate of the processing liquid L measured by the flowmeter 39B is outputted to the controller 5.

The branch path 41 is a flow path for sampling the concentration of the processing liquid L flowing through the circulation path 32B. This branch path 41 is provided with the flowmeter 42, the concentration meter 43, and the valve 44 in this order from the upstream side with respect to the branching portion 38.

The flowmeter 42 measures the flow rate of the processing liquid L flowing through the branch path 41. A measurement value of the flow rate of the processing liquid L measured by the flowmeter 42 is outputted to the controller 5.

The concentration meter 43 measures the concentration of the processing liquid L flowing through the branch path 41 to measure the concentration of the processing liquid L flowing through the circulation path 32. The concentration meter 43 measures, for example, a phosphoric acid concentration of the processing liquid L flowing through the branch path 41. A measurement value of the concentration of the processing liquid L measured by the concentration meter 43 is outputted to the controller 5. The valve 44 controls whether or not the processing liquid L is to be supplied from the branching portion 38 to the outer tub 21b.

Now, details of the startup processing of the substrate processing apparatus 1 using the processing liquid supply system 3 according to the first modification example will be explained with reference to FIG. 5 and FIG. 6.

As shown in FIG. 5, the controller 5 (see FIG. 1) operates the pumps 33A and 33B (see FIG. 7) as a circulation processing from the time T03, which is the same as in the above-described exemplary embodiment. Thus, the controller 5 allows the processing liquid L (see FIG. 7) to flow through the circulation paths 32A and 32B (see FIG. 7), thereby performing a charging processing of filling the circulation paths 32A and 32B with the processing liquid L.

In the charging processing according to the first modification example, the controller operates the pumps 33A and 33B, which are magnetic levitation pumps, under a rotation speed control, as shown in FIG. 5. Also, the controller 5 operates the pumps 33A and 33B at the predetermined rotation speed Rs in the charging processing.

In this way, by operating the pumps 33A and 33B under the rotation speed control in the charging processing, the pumps 33A and 33B can be stably operated even when the circulation paths 32A and 32B are not filled with the processing liquid L and thus a flow rate feedback control is difficult to perform. Therefore, according to the first modification example, the circulation paths 32A and 32B can be stably filled with the processing liquid L.

Further, in the first modification example, the pumps 33A and 33B need to be operated at the rotation speed Rs at which the measurement values of the flowmeters 39A and 39B (see FIG. 7) become equal to or greater than the minimum circulation flow rate FL and cavitation does not occur inside the pumps 33A and 33B in the charging processing. This allows the circulation paths 32A and 32B to be stably filled with the processing liquid L.

Furthermore, the charging processing according to the first modification example needs to be carried out from the time T03 for the period P1, which is confirmed in advance as being sufficient to fill both of the circulation paths 32A and 32B with the processing liquid L, as shown in FIG. 5. This allows the circulation paths 32A and 32B to be filled with the processing liquid L more reliably.

Following the charging processing described so far, the controller 5 performs a stop processing of stopping the pumps 33A and 33B from the time T11, which is the same as in the above-described exemplary embodiment, thereby stopping the circulation of the processing liquid L in the circulation paths 32A and 32B in the circulation processing according to the first modification example. As a result, measurement values obtained by the flowmeters 39A and 39B become zero, as shown in FIG. 5.

In this way, in the circulation processing according to the first modification example, by performing the stop processing of stopping the circulation of the processing liquid L after the charging processing, both of the circulation paths 32A and 32B can be brought into a state in which a circulation flow rate therein is zero. Therefore, according to the first modification example, the circulation flow can be started up in the state that the flow rates in the circulation paths 32A and 32B are the same.

Next, in the circulation processing according to the first modification example, the controller 5 performs, from the time T12, which is the same as in the above-described exemplary embodiment, a first circulation processing of circulating the processing liquid L such that the processing liquid L (see FIG. 7) flowing through both the circulation paths 32A and 32B (see FIG. 7) reaches the initial set flow rate F1, as shown in FIG. 6.

To carry out this first circulation processing, the controller 5 (see FIG. 1) switches the operation mode of the pumps 33A and 33B (see FIG. 7) from a rotation speed control to a flow rate feedback control.

Then, in the first circulation processing, the controller 5 operates the pumps 33A and 33B, while setting the set flow rates of the processing liquid L in the circulation paths 32A and 32B to the initial set flow rate F1. As a result, as shown in FIG. 6, the measurement values of the flowmeters 39A and 39B (see FIG. 7) gradually rise from zero.

Further, in the first modification example, from the time T05 after the start of the first circulation processing, the controller 5 operates the heaters 36A and 36B (see FIG. 7) to perform a temperature control processing for the processing liquid L.

In this way, in the first modification example, the heaters 36A and 36B are not operated immediately after the minimum circulation flow rate FL is reached, but are operated after a margin of the period P2.

This allows the heaters 36A and 36B to be operated after sufficient circulation flow rates are secured in the circulation paths 32A and 32B, which makes it possible to suppress a problem that might be caused by operating the heaters 36A and 36B when the flow rates in the circulation paths 32A and 32B are not sufficient.

In the first modification example, the measurement value of the thermometer 45 gradually rises from the temperature A0 from the time T05 when the temperature control processing is begun. Further, in the first modification example, as the processing liquid L overflows from the inner tub 21a into the outer tub 21b and the temperature of the processing liquid L increases, the moisture in the processing liquid L evaporates from the processing tub 21, so that the measurement value of the concentration meter 43 gradually rises from the concentration C0.

Then, in the first modification example, after a timepoint when the measurement values of both the flowmeters 39A and 39B reach the initial set flow rate F1, the controller 5 performs a second circulation processing in which the pumps 33A and 33B are operated so that the flow rates in the circulation paths 32A and 32B reach the preset processing set flow rate F2.

That is, in the circulation processing according to the first modification example, the pumps 33A and 33B are operated so that the flow rates in the circulation paths 32A and 32B reach the processing set flow rate F2 after the flow rates in the circulation paths 32A and 32B are first stabilized to the initial set flow rate F1.

Thus, the controller 5 can stably perform a feedback control to secure the processing set flow rate F2 in both of the circulation paths 32A and 32B. Therefore, according to the first modification example, the flow rates of the processing liquid L discharged from the multiple dischargers 23 via the circulation paths 32A and 32B can be made the same, so that non-uniformity in the temperature of the processing liquid L in the inner tub 21a can be reduced.

Furthermore, as compared to a case where the pumps 33A and 33B are operated so that the flow rates in the circulation paths 32A and 32B increase from zero to the processing set flow rate F2 at once, it is possible to suppress cavitation from occurring inside the pumps 33A and 33B even if the flow rate of the processing liquid L is increased.

Therefore, according to the first modification example, the flow rate of the processing liquid L sent from the circulation paths 32A and 32B back into the processing tub 21 can be increased.

Furthermore, in the first modification example, the controller 5 may start a second circulation processing when the measurement values of the flowmeters 39A and 39B all reach the initial set flow rate F1 and the measurement value of the concentration meter 43 falls within a predetermined concentration range (between the lower limit concentration CTL and the upper limit concentration CTH).

Accordingly, since the pumps 33A and 33B can be operated to achieve the processing set flow rate F2 after the viscosity of the processing liquid L is brought close to a viscosity level required for processing the wafer W, occurrence of cavitation inside the pumps 33A and 33B can be further suppressed even if the flow rate of the processing liquid L is increased.

Therefore, according to the first modification example, the flow rate of the processing liquid L sent from the circulation paths 32A and 32B back to the processing tub 21 can be stably increased.

In addition, in the first modification example, the controller 5 may start the second circulation processing when the measurement values of the flowmeters 39A and 39B all reach the initial set flow rate F1 and the measurement value of the thermometer 45 falls within a predetermined temperature range (between the lower limit temperature ATL and the upper limit temperature ATH).

This allows the pumps 33A and 33B to be operated to achieve the processing set flow rate F2 after the viscosity of the processing liquid L is brought close to the viscosity level for processing the wafer W, occurrence of cavitation inside the pumps 33A and 33B can be further suppressed even if the flow rate of the processing liquid L is increased.

Therefore, according to the first modification example, the flow rate of the processing liquid L sent from the circulation paths 32A and 32B back to the processing tub 21 can be stably increased.

Furthermore, in the first modification example, the controller 5 may start the second circulation processing from the time T15 when the measurement values of the flowmeters 39A and 39B have reached the initial set flow rate F1, the measurement value of the concentration meter 43 has reached the predetermined concentration range, and the measurement value of the thermometer 45 has reached the predetermined temperature range.

This allows the pumps 33A and 33B to be operated to achieve the processing set flow rate F2 after the viscosity of the processing liquid L is brought further close to the viscosity level for processing the wafer W. Thus, even if the flow rate of the processing liquid L is increased, occurrence of cavitation inside the pumps 33A and 33B can be further suppressed.

Therefore, according to the first modification example, the flow rate of the processing liquid L sent from the circulation paths 32A and 32B back into the processing tub 21 can be stably increased.

The controller 5 starts the second circulation processing from the time T15, and gradually increases the set flow rates of the pumps 33A and 33B from the time T15 to the time T16. Then, the controller 5 sets the set flow rates of the pumps 33A and 33B to the processing set flow rate F2 for processing the wafer W at the time T16.

As a result, the measurement values of the flowmeters 39A and 39B become the processing set flow rate F2 for processing the wafer W, the measurement value of the concentration meter 43 becomes the processing set concentration CS for processing the wafer W, and the measurement value of the thermometer 45 becomes the processing set temperature AS for processing the wafer W. Then, the series of processes of the startup processing according to the first modification example are completed.

In the first modification example, by gradually increasing the set flow rates of the pumps 33A and 33B from the time T15 to the time T16, a rapid change in the flow rates in the circulation paths 32A and 32B can be suppressed. Thus, according to the first modification example, it is possible to suppress occurrence of cavitation inside the pumps 33A and 33B.

In the example of FIG. 7 described so far, the circulation path 32 includes the two circulation paths 32A and 32B. However, the present disclosure is not limited thereto, and the circulation path 32 may include three or more circulation paths.

### Second Modification Example

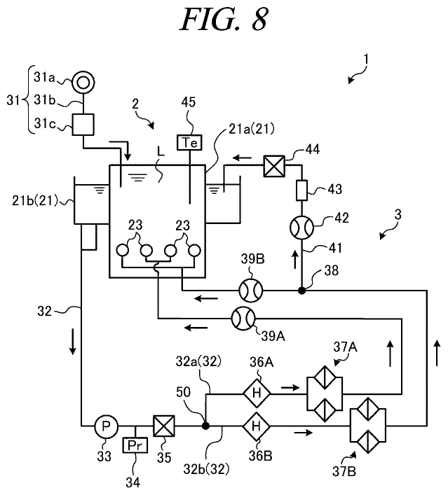

Now, the processing liquid supply system 3 according to a second modification example and a startup processing using this processing liquid supply system 3 will be explained with reference to FIG. 8 in addition to FIG. 5 and FIG. 6. FIG. 8 is a diagram illustrating a configuration example of the processing liquid supply system 3 according to the second modification example.

The second modification example shown in FIG. 8 is different from one or more embodiments and the first modification example described above in the configuration of the circulation path 32. Specifically, in the second modification example, the single circulation path 32 is branched at a branching portion 50 on its way into multiple (two in the shown example) branch circulation paths 32a and 32b.

With this configuration, the feed flow rate of the processing liquid L returned from the circulation path 32 back into the processing tub 21 can be increased, as compared to the case where the single circulation path 32 is provided from the uppermost stream to the downmost stream for the single processing tub 21.

The circulation path 32 is provided with the pump 33, the pressure gauge 34, the check valve 35, and the branching portion 50 in this order from the upstream side with respect to the processing tub 21. Also, the circulation path 32 is branched into the branch circulation paths 32a and 32b at the branching portion 50.

The pump 33 forms a circulation flow of the processing liquid L that flows out from the processing tub 21, passes through the circulation path 32 and the branch circulation paths 32a and 32b, and returns back into the processing tub 21. The pump 33 is, by way of non-limiting example, a magnetic levitation pump. However, the pump 33 of the present disclosure is not limited to the magnetic levitation pump, and may be a diaphragm pump or the like.

The pressure gauge 34 measures the pressure of the processing liquid L flowing through the circulation path 32. A measurement value of the pressure of the processing liquid L measured by the pressure gauge 34 is outputted to the controller 5 (see FIG. 1). The check valve 35 suppresses a backflow of the processing liquid L flowing through the circulation path 32. The check valve 35 is, for example, an air-operated valve.

In this way, by disposing the pump 33 upstream of the branching portion 50, the processing liquid L can be sent to the multiple branch circulation paths 32a and 32b without needing to increase the number of the pump 33. Therefore, according to the second modification example, the manufacturing cost of the processing liquid supply system 3 can be reduced.

The branch circulation path 32a is provided with a heater 36A, a filter 37A, and a flowmeter 39A in this order from the upstream side with respect to the branching portion 50.

The heater 36A heats the processing liquid L flowing through the branch circulation path 32a. In the second modification example, by heating the processing liquid L with this heater 36A, the processing liquid L stored in the processing tub 21 is heated up to the processing set temperature AS (see FIG. 5) required for processing the wafer W.

The filter 37A removes contaminants such as particles contained in the processing liquid L flowing through the branch circulation path 32a. The filter 37A may include multiple filter modules arranged in parallel.

The flowmeter 39A measures the flow rate of the processing liquid L flowing through the branch circulation path 32a. A measurement value of the flow rate of the processing liquid L measured by the flowmeter 39A is outputted to the controller 5.

The branch circulation path 32b is provided with a heater 36B, a filter 37B, a branching portion 38, and a flowmeter 39B in this order from the upstream side with respect to the branching portion 50.

The heater 36B heats the processing liquid L flowing through the branch circulation path 32b. In the second modification example, by heating the processing liquid L with this heater 36B, the processing liquid L stored in the processing tub 21 is heated up to the processing set temperature AS required for processing the wafer W.

The filter 37B removes contaminants such as particles contained in the processing liquid L flowing through the branch circulation path 32b. The filter 37B may include multiple filter modules arranged in parallel.

The branch path 41 leading to the outer tub 21b of the processing tub 21 is branched from the branching portion 38. The flowmeter 39B measures the flow rate of the processing liquid L flowing through the branch circulation path 32b. A measurement value of the flow rate of the processing liquid L measured by the flowmeter 39B is outputted to the controller 5.

The branch path 41 is a flow path for sampling the concentration of the processing liquid L flowing through the branch circulation path 32b. This branch path 41 is provided with the flowmeter 42, the concentration meter 43, and the valve 44a in this order from the upstream side with respect to the branching portion 38.

The flowmeter 42 measures the flow rate of the processing liquid L flowing through the branch path 41. A measurement value of the flow rate of the processing liquid L measured by the flowmeter 42 is outputted to the controller 5.

The concentration meter 43 measures the concentration of the processing liquid L flowing through the branch path 41 to measure the concentration of the processing liquid L flowing through the circulation path 32. The concentration meter 43 measures, for example, a phosphoric acid concentration of the processing liquid L flowing through the branch path 41. A measurement value of the concentration of the processing liquid L measured by the concentration meter 43 is outputted to the controller 5. The valve 44 controls whether or not the processing liquid L is to be supplied from the branching portion 38 to the outer tub 21b.

Now, details of the startup processing of the substrate processing apparatus 1 using the processing liquid supply system 3 according to the second modification example will be explained with reference to FIG. 5 and FIG. 6.

As shown in FIG. 5, the controller 5 (see FIG. 1) operates the pumps 33 (see FIG. 8) as a circulation processing from the time T03, which is the same as in the above-described exemplary embodiment. Thus, the controller 5 allows the processing liquid L (see FIG. 8) to flow through the circulation path 32 (see FIG. 8) and the branch circulation paths 32a and 32b (see FIG. 8), thereby performing a charging processing of filling the circulation path 32 and the branch circulation paths 32a and 32b with the processing liquid L.

In the charging processing according to the second modification example, the controller 5 operates the pump 33, which is a magnetic levitation pump, under a rotation speed control, as shown in FIG. 5. Also, the controller 5 operates the pump 33 at the predetermined rotation speed Rs in the charging processing.

In this way, by operating the pump 33 under the rotation speed control in the charging processing, the pump 33 can be stably operated even when the circulation path 32 and the branch circulation paths 32a and 32b are not filled with the processing liquid L and thus a flow rate feedback control is difficult to perform. Therefore, according to the second modification example, the circulation path 32 and the branch circulation paths 32a and 32b can be stably filled with the processing liquid L.

Further, in the second modification example, the pump 33 needs to be operated at the rotation speed Rs at which the measurement values of the flowmeters 39A and 39B (see FIG. 8) become equal to or greater than the minimum circulation flow rate FL and cavitation does not occur inside the pump 33 in the charging processing. This allows the circulation path 32 and the branch circulation paths 32a and 32b to be stably filled with the processing liquid L.

Furthermore, the charging processing according to the second modification example needs to be carried out from the time T03 for the period P1, which is confirmed in advance as being sufficient to fill all of the circulation path 32 and the branch circulation paths 32a and 32b with the processing liquid L, as shown in FIG. 5. This allows the circulation path 32 and the branch circulation paths 32a and 32b to be filled with the processing liquid L more reliably.

Following the charging processing described so far, the controller 5 performs a stop processing of stopping the pump 33 from the time T11, which is the same as in the above-described exemplary embodiment, thereby stopping the circulation of the processing liquid L in the circulation path 32 and the branch circulation paths 32a and 32b in the circulation processing according to the second modification example. As a result, the measurement values of the flowmeters 39A and 39B become zero, as shown in FIG. 5.

In this way, in the circulation processing according to the second modification example, by performing the stop processing of stopping the circulation of the processing liquid L after the charging processing, both of the branch circulation paths 32a and 32b can be brought into a state in which a circulation flow rate therein is zero. Therefore, according to the second modification example, the circulation flow can be started up in the state that the flow rates in the branch circulation paths 32a and 32b are the same.

Next, in the circulation processing according to the second modification example, the controller 5 performs, from the time T12, which is the same as in the above-described exemplary embodiment, a first circulation processing of circulating the processing liquid L such that the processing liquid L (see FIG. 8) flowing through the branch circulation paths 32a and 32b (see FIG. 8) reaches the initial set flow rate F1, as shown in FIG. 6.

To carry out this first circulation processing, the controller 5 (see FIG. 1) switches the operation mode of the pump 33 (see FIG. 8) from a rotation speed control to a flow rate feedback control.

Then, in the first circulation processing, the controller 5 operates the pump 33, while setting the set flow rates of the processing liquid L in the branch circulation paths 32a and 32b to the initial set flow rate F1. As a result, as shown in FIG. 6, the measurement values of the flowmeters 39A and 39B (see FIG. 8) gradually rise from zero.

Further, in the second modification example, from the time T05 after the start of the first circulation processing, the controller 5 operates the heaters 36A and 36B (see FIG. 8) to perform a temperature control processing for the processing liquid L.

In this way, in the second modification example, the heaters 36A and 36B are not operated immediately after the minimum circulation flow rate FL is reached, but are operated after a margin of the period P2.

This allows the heaters 36A and 36B to be operated after sufficient circulation flow rates are achieved in the branch circulation paths 32a and 32b, which makes it possible to suppress a problem that might be caused by operating the heaters 36A and 36B when the flow rates in the branch circulation paths 32a and 32b are not sufficient.

In the second modification example, the measurement value of the thermometer 45 gradually rises from the temperature A0 from the time T05 when the temperature control processing is begun. Further, in the second modification example, as the processing liquid L overflows from the inner tub 21a into the outer tub 21b and the temperature of the processing liquid L increases, the moisture in the processing liquid L evaporates from the processing tub 21, so that the measurement value of the concentration meter 43 gradually rises from the concentration C0.

Then, in the second modification example, after a timepoint when the measurement values of both the flowmeters 39A and 39B reach the initial set flow rate F1, the controller 5 performs a second circulation processing in which the pump 33 is operated so that the flow rates in the branch circulation paths 32a and 32b reach the preset processing set flow rate F2.

That is, in the circulation processing according to the second modification example, the pump 33 is operated so that the flow rates in the branch circulation paths 32a and 32b reach the processing set flow rate F2 after the flow rates in the branch circulation paths 32a and 32b are first stabilized to the initial set flow rate F1.

Thus, the controller 5 can stably perform a feedback control to secure the processing set flow rate F2 in both of the branch circulation paths 32a and 32b. Therefore, according to the second modification example, the flow rates of the processing liquid L discharged from the multiple dischargers 23 via the branch circulation paths 32a and 32b can be made the same, so that non-uniformity in the temperature of the processing liquid L in the inner tub 21a can be reduced.

Besides, as compared to a case where the pump 33 is operated so that the flow rates in the branch circulation paths 32a and 32b increase from zero to the processing set flow rate F2 at once, it is possible to suppress cavitation from occurring inside the pump 33 even if the flow rate of the processing liquid L is increased.

Therefore, according to the second modification example, the flow rate of the processing liquid L sent from the circulation path 32 and the branch circulation paths 32a and 32b back to the processing tub 21 can be increased.

Furthermore, in the second modification example, the controller 5 may start a second circulation processing when the measurement values of the flowmeters 39A and 39B all reach the initial set flow rate F1 and the measurement value of the concentration meter 43 falls within a predetermined concentration range (between the lower limit concentration CTL and the upper limit concentration CTH).

Accordingly, since the pump 33 can be operated to achieve the processing set flow rate F2 after the viscosity of the processing liquid L is brought close to a viscosity level for processing the wafer W, occurrence of cavitation inside the pump 33 can be further suppressed even if the flow rate of the processing liquid L is increased.

Therefore, according to the second modification example, the flow rate of the processing liquid L sent from the circulation path 32 and the branch circulation paths 32a and 32b back to the processing tub 21 can be stably increased.

In addition, in the second modification example, the controller 5 may start the second circulation processing when the measurement values of the flowmeters 39A and 39B all reach the initial set flow rate F1 and the measurement value of the thermometer 45 falls within a predetermined temperature range (between the lower limit temperature ATL and the upper limit temperature ATH).

This allows the pump 33 to be operated to achieve the processing set flow rate F2 after the viscosity of the processing liquid L is brought close to the viscosity level for processing the wafer W, so that occurrence of cavitation inside the pump 33 can be further suppressed even if the flow rate of the processing liquid L is increased.

Therefore, according to the second modification example, the flow rate of the processing liquid L sent from the circulation path 32 and the branch circulation paths 32a and 32b back to the processing tub 21 can be stably increased.

Furthermore, in the second modification example, the controller 5 may start the second circulation processing from the time T15 when the measurement values of the flowmeters 39A and 39B have reached the initial set flow rate F1, the measurement value of the concentration meter 43 has reached the predetermined concentration range, and the measurement value of the thermometer 45 has reached the predetermined temperature range.

This allows the pump 33 to be operated to achieve the processing set flow rate F2 after the viscosity of the processing liquid L is brought further close to the viscosity level for processing the wafer W. Thus, even if the flow rate of the processing liquid L is increased, occurrence of cavitation inside the pumps 33 can be further suppressed.

Therefore, according to the second modification example, the flow rate of the processing liquid L sent from the circulation path 32 and the branch circulation paths 32a and 32b back into the processing tub 21 can be stably increased.

The controller 5 starts the second circulation processing from the time T15, and gradually increases the set flow rate of the pump 33 from the time T15 to the time T16. Then, the controller 5 sets the set flow rate of the pump 33 to the processing set flow rate F2 for processing the wafer W at the time T16.

As a result, the measurement values of the flowmeters 39A and 39B become the processing set flow rate F2 for processing the wafer W, the measurement value of the concentration meter 43 becomes the processing set concentration CS for processing the wafer W, and the measurement value of the thermometer 45 becomes the processing set temperature AS for processing the wafer W. Then, the series of processes of the startup processing according to the second modification example are completed.

In the second modification example, by gradually increasing the set flow rate of the pump 33 from the time T15 to the time T16, a rapid change in the flow rates in the circulation path 32 and the branch circulation paths 32a and 32b can be suppressed. Thus, according to the second modification example, it is possible to suppress occurrence of cavitation inside the pump 33.

In the example of FIG. 8 described so far, the circulation path 32 is branched into the two branch circulation paths 32a and 32b on its way. However, the present disclosure is not limited thereto, and the circulation path 32 may be branched into three or more branch circulation paths.

The processing liquid supply system 3 according to one or more embodiments includes the processing liquid supply 31, the circulation path 32 (32A and 32B), the pump 33 (33A and 33B), the flowmeter 39 (39A and 39B), and the controller 5. The processing liquid supply 31 supplies the processing liquid L to the processing tub 21 in which the substrate (wafer W) is to be immersed and processed. The circulation path 32 (32A and 32B) allows the processing liquid L to flow out from the processing tub 21 and return back into the processing tub 21. The pump 33 (33A and 33B) and the flowmeter 39 (39A and 39B) are provided in the circulation path 32 (32A and 32B). The controller 5 controls the individual components. Also, the controller 5 performs storage processing, a charging processing, a first circulation processing, and a second circulation processing. In the storage processing, the processing liquid L is supplied from the processing liquid supply 31 and stored in the processing tub 21. In the charging processing, the pump 33 (33A and 33B) is operated to allow the processing liquid L to flow through the circulation path 32 (32A and 32B), thus filling the circulation path 32 (32A and 32B) with the processing liquid L. In the first circulation processing, the pump 33 (33A and 33B) is operated after the charging processing so that the processing liquid L passing through the circulation path 32 (32A and 32B) reaches the initial set flow rate F1, thus allowing the processing liquid L to be circulated through the circulation path 32 (32A and 32B). In the second circulation processing, the pump 33 (33A and 33B) is operated to achieve the processing set flow rate F2 for processing the substrate (wafer W) after the measurement value of the flowmeter 39 (39A and 39B) becomes the initial set flow rate F1. This makes it possible to increase the flow rate of the processing liquid L sent from the circulation path 32 back into the processing tub 21.

Further, the processing liquid supply system 3 according to one or more embodiments further includes the heater 36 (36A and 36B) provided in the circulation path 32 (32A and 32B) and the thermometer 45 configured to measure the temperature of the processing liquid L flowing through the circulation path 32 (32A and 32B). In the first circulation processing, the controller 5 operates the heater 36 (36A and 36B) to heat the processing liquid L, and starts the second circulation processing when the measurement value of the flowmeter 39 (39A and 39B) has reached the initial set flow rate F1 and the measurement value of the thermometer 45 has reached within a predetermined temperature range. This makes it possible to stably increase the flow rate of the processing liquid L sent from the circulation path 32 (32A and 32B) back into the processing tub 21.

Moreover, the processing liquid supply system 3 according to one or more embodiments further includes the concentration meter 43 configured to measure the concentration of the processing liquid L flowing through the circulation path 32 (32A and 32B). In the first circulation processing, the controller 5 operates the heater 36 (36A and 36B) to heat the processing liquid L. Then, the controller 5 starts the second circulation processing when the measurement value of the flowmeter 39 (39A and 39B) has reached the initial set flow rate F1, the measurement value of the thermometer 45 has reached within a predetermined temperature range, and the measurement value of the concentration meter 43 has reached within a predetermined concentration range. This makes it possible to stably increase the flow rate of the processing liquid L sent from the circulation path 32 (32A and 32B) back to the processing tub 21.

Also, the processing liquid supply system 3 according to one or more embodiments further includes the heater 36 (36A and 36B) provided in the circulation path 32 (32A and 32B) and the concentration meter 43 configured to measure the concentration of the processing liquid L flowing through the circulation path 32 (32A and 32B). In the first circulation processing, the controller 5 operates the heater 36 (36A and 36B) to heat the processing liquid L. Then, the controller 5 starts the second circulation processing when the measurement value of the flowmeter 39 (39A and 39B) has reached the initial set flow rate F1 and the measurement value of the concentration meter 43 has reached within a predetermined concentration range. This makes it possible to stably increase the flow rate of the processing liquid L sent from the circulation path 32 (32A and 32B) back into the processing tub 21.

Besides, in the processing liquid supply system 3 according to one or more embodiments, the circulation paths 32A and 32B are provided in plural numbers. The pumps 33A and 33B and the flowmeters 39A and 39B are provided in the circulation paths 32A and 32B, respectively. In the charging processing, the controller 5 operates the pumps 33A and 33B respectively provided in the circulation paths 32A and 32B to fill all the circulation paths 32A and 32B with the processing liquid L. Further, between the charging processing and the first circulation processing, the controller 5 stops the operation of all the pumps 33A and 33B to perform a stop processing of stopping the circulation in all of the circulation paths 32A and 32B. This makes it possible to start up a circulation flow in the state where all the circulation paths 32A and 32B have the same flow rate.

In addition, in the processing liquid supply system 3 according to one or more embodiments, the controller 5 starts the second circulation processing when the measurement values of all the flowmeters 39A and 39B have reached the initial set flow rate F1 in the first circulation processing. This makes it possible to reduce non-uniformity in the temperature of the processing liquid L in the inner tub 21a.

Further, in the processing liquid supply system 3 according to one or more embodiments, the circulation path 32 is branched downstream of the pump 33 into the multiple branch circulation paths 32a and 32b. The flowmeters 39A and 39B are provided in the branch circulation paths 32a and 32b, respectively. In the charging processing, the controller 5 operates the pump 33 to fill all the branch circulation paths 32a and 32b with the processing liquid L. Further, between the charging processing and the first circulation processing, the controller 5 stops the operation of the pump 33 to perform a stop processing of stopping the circulation in all of the branch circulation paths 32a and 32b. This makes it possible to start up a circulation flow in the state where all the branch circulation paths 32a and 32b have the same flow rate.

Moreover, in the processing liquid supply system 3 according to one or more embodiments, the pump 33 (33A and 33B) is a magnetic levitation pump configured to force-feed the processing liquid L as its rotator is rotated in the processing liquid L while being magnetically levitated. The controller 5 performs the force-feeding of the processing liquid L while controlling the rotation speed of the rotator based on the measurement value of the flowmeter 39 (39A and 39B). This makes it possible to increase the flow rate of the processing liquid L sent from the circulation path 32 back into the processing tub 21.

Additionally, in the processing liquid supply system 3 according to one or more embodiments, the controller 5 operates the pump 33 (33A and 33B) while fixing the rotation speed of the rotator to a preset rotation speed in the charging processing. This makes it possible to stably fill the circulation path 32 with the processing liquid L.

### Sequence of Control Processing

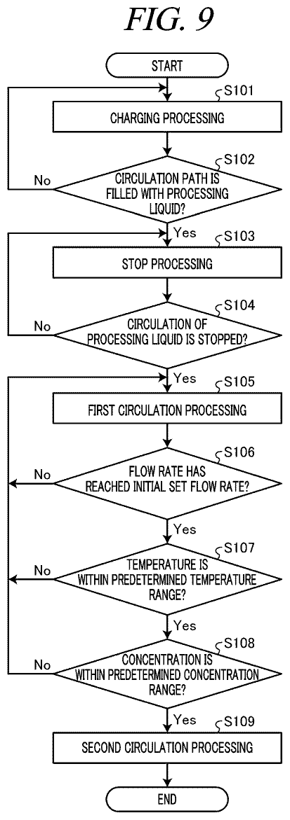

Now, a sequence of a control processing according to one or more embodiments will be explained with reference to FIG. 9 to FIG. 11. FIG. 9 is a flowchart showing an example sequence of a control processing performed by the processing liquid supply system 3 according to one or more embodiments.

In the control processing according to one or more embodiments, the controller 5 first performs a charging processing of operating the pump 33 to allow the processing liquid L to flow through the circulation path 32, thereby filling the circulation path 32 with the processing liquid L (process S101).

Next, the controller 5 determines whether the circulation path 32 is filled with the processing liquid L (process S102). For example, if the charging processing (process S101) is performed for the predetermined period P1 or more, the controller 5 may make a determination that the circulation path 32 is filled with the processing liquid L.

If it is determined that the circulation path 32 is filled with the processing liquid L (process S102, Yes), the controller 5 performs a stop processing of stopping the pump 33 to stop the circulation of the processing liquid L in the circulation path 32 (process S103). If, on the other hand, it is determined that the circulation path 32 is not filled with the processing liquid L (process S102, No), the processing returns back to the process S101.

Following the stop processing (process S103), the controller 5 determines whether or not the circulation of the processing liquid L is stopped in the circulation path 32 (process S104). For example, if the stop processing (process S103) is performed for a preset period or more, the controller 5 may make a determination that the circulation of the processing liquid L is stopped in the circulation path 32.

Then, when it is determined that the circulation of the processing liquid L is stopped in the circulation path 32 (process S104, Yes), the controller 5 performs a first circulation processing of circulating the processing liquid L so that the processing liquid L flowing through the circulation path 32 reaches the predetermined initial set flow rate F1 (process S105). On the other hand, when it is determined that the circulation of the processing liquid L is not stopped in the circulation path 32 (process S104, No), the processing returns back to the process S103.

Following the first circulation processing (process S105), the controller 5 determines whether the flow rate of the processing liquid L in the circulation path 32 has reached the initial set flow rate F1 (process S106). Then, if it is determined that the flow rate of the processing liquid L in the circulation path 32 has reached the initial set flow rate F1 (process S106, Yes), the controller 5 determines whether the temperature of the processing liquid L is within a predetermined temperature range (between the lower limit temperature ATL and the upper limit temperature ATH) (process S107).

If it is determined that the temperature of the processing liquid L is within the predetermined temperature range (process S107, Yes), the controller 5 determines whether the concentration of the processing liquid L is within the predetermined concentration range (between the lower limit concentration CTL and the upper limit concentration CTH) (process S108).

When it is determined that the concentration of the processing liquid L is within the predetermined concentration range (process S108, Yes), the controller 5 performs a second circulation processing of operating the pump 33 so that the predetermined processing set flow rate F2 for processing the wafer W is achieved in the circulation path 32 (process S109). Then, the series of processes of the start-up processing are completed.

In the process S106, if it is determined that the flow rate of the processing liquid L in the circulation path 32 has not reached the initial set flow rate F1 (process S106, No), the processing returns back to the process S105.

Also, in the process S107, if it is determined that the temperature of the processing liquid L is not within the predetermined temperature range (process S107, No), the processing returns back to the process S105.

Also, in the process S108, if it is determined that the concentration of the processing liquid L is not within the predetermined concentration range (process S108, No), the processing returns back to the process S105.

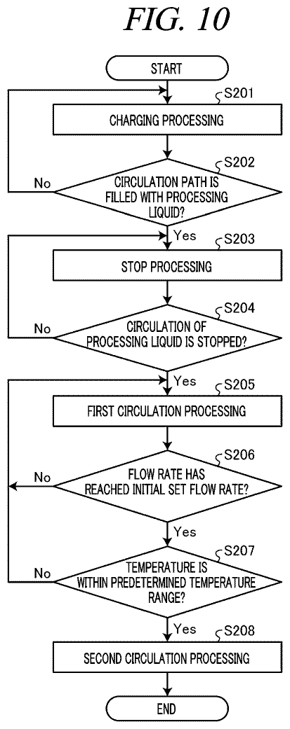

FIG. 10 is a flowchart showing another example sequence of the control processing performed by the processing liquid supply system 3 according to one or more embodiments.

In the control processing shown in FIG. 10, the controller 5 first performs a charging processing of operating the pump 33 to allow the processing liquid L to flow through the circulation path 32, thereby filling the circulation path 32 with the processing liquid L (process S201).

Next, the controller 5 determines whether the circulation path 32 is filled with the processing liquid L (process S202). Then, if it is determined that the circulation path 32 is filled with the processing liquid L (process S202, Yes), the controller 5 performs a stop processing of stopping the pump 33 to stop the circulation of the processing liquid L in the circulation path 32 (process S203).

On the other hand, if it is determined that the circulation path 32 is not filled with the processing liquid L (process S202, No), the processing returns back to the process S201.

Following the stop processing (process S203), the controller 5 determines whether or not the circulation of the processing liquid L is stopped in the circulation path 32 (process S204). If it is determined that the circulation of the processing liquid L is stopped in the circulation path 32 (process S204, Yes), the controller 5 performs a first circulation processing of circulating the processing liquid L so that the processing liquid L flowing through the circulation path 32 reaches the initial set flow rate F1 (process S205).

On the other hand, if it is determined that the circulation of the processing liquid L in the circulation path 32 is not stopped (process S204, No), the processing returns back to the process S203.

Following the first circulation processing (process S205), the controller 5 determines whether the flow rate of the processing liquid L in the circulation path 32 has reached the initial set flow rate F1 (process S206). If it is determined that the flow rate of the processing liquid L in the circulation path 32 has reached the initial set flow rate F1 (process S206, Yes), the controller 5 determines whether the temperature of the processing liquid L is within a predetermined temperature range (process S207).

If it is determined that the temperature of the processing liquid L is within the predetermined temperature range (process S207, Yes), the controller 5 performs a second circulation processing of operating the pump 33 so that the processing set flow rate F2 for processing the wafer W is achieved in the circulation path 32 (process S208). Then, the series of processes of the start-up processing are completed.

In addition, in the process S206, if it is determined that the flow rate of the processing liquid L in the circulation path 32 has not reached the initial set flow rate F1 (process S206, No), the processing returns back to the process S205.

Also, in the process S207, if it is determined that the temperature of the processing liquid L is not within the predetermined temperature range (process S207, No), the processing returns back to the process S205.

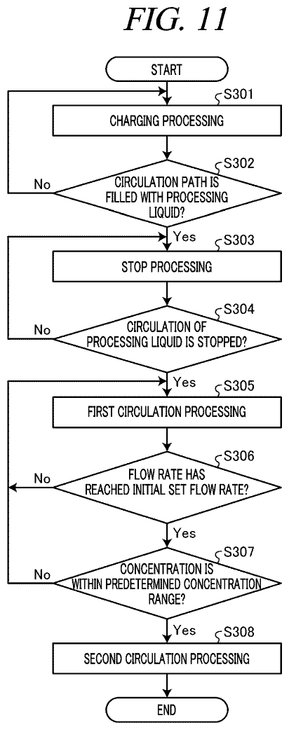

FIG. 11 is a flowchart showing still another example sequence of the control processing performed by the processing liquid supply system 3 according to one or more embodiments.

In the control processing shown in FIG. 11, the controller 5 first performs a charging processing of operating the pump 33 to allow the processing liquid L to flow through the circulation path 32, thereby filling the circulation path 32 with the processing liquid L (process S301).

Next, the controller 5 determines whether the circulation path 32 is filled with the processing liquid L (process S302). If it is determined that the circulation path 32 is filled with the processing liquid L (process S302, Yes), the controller 5 performs a stop processing of stopping the pump 33 to stop the circulation of the processing liquid L in the circulation path 32 (process S303).

On the other hand, if it is determined that the circulation path 32 is not filled with the processing liquid L (process S302, No), the processing returns back to the process S301.

Following the stop processing (process S303), the controller 5 determines whether or not the circulation of the processing liquid L is stopped in the circulation path 32 (process S304). If it is determined that the circulation of the processing liquid L is stopped in the circulation path 32 (process S304, Yes), the controller 5 performs a first circulation processing of circulating the processing liquid L so that the processing liquid L flowing through the circulation path 32 reaches the predetermined initial set flow rate F1 (process S305).

On the other hand, if it is determined that the circulation of the processing liquid L in the circulation path 32 is not stopped (process S304, No), the processing returns back to the process S303.

Following the first circulation processing (process S305), the controller 5 determines whether the flow rate of the processing liquid L in the circulation path 32 has reached the initial set flow rate F1 (process S306). If it is determined that the flow rate of the processing liquid L in the circulation path 32 has reached the initial set flow rate F1 (process S306, Yes), the controller 5 determines whether the concentration of the processing liquid L is within a predetermined concentration range (process S307).

If it is determined that the concentration of the processing liquid L is within the predetermined concentration range (process S307, Yes), the controller 5 performs a second circulation processing of operating the pump 33 so that the processing set flow rate F2 for processing the wafer W is achieved in the circulation path 32 (process S308). Then, the series of processes of the start-up processing are completed.

In addition, in the process S306, if it is determined that the flow rate of the processing liquid L in the circulation path 32 has not reached the initial set flow rate F1 (process S306, No), the processing returns back to the process S305.

Also, in the process S307, if it is determined that the concentration of the processing liquid L is not within the predetermined concentration range (process S307, No), the processing returns back to the process S305.

A processing liquid supply method according to one or more embodiments includes a storage processing, a charging processing (processes S101, S201 and S301), a first circulation processing (processes S105, S205 and S305), and a second circulation processing (processes S109, S208 and S308). In the storage processing, the processing liquid L is supplied to and stored in the processing tub 21 in which the substrate (wafer W) is to be immersed and processed. In the charging processing, the pump 33 (33A and 33B) provided in the circulation path 32 (32A and 32B) is operated to allow the processing liquid L to flow through the circulation path 32 (32A and 32B), thus filling the circulation path 32 (32A and 32B) with the processing liquid L. The circulation path 32 (32A and 32B) allows the processing liquid L to flow out from the processing tub 21 and then return to the processing tub 21. In the first circulation processing, the processing liquid L is circulated through the circulation path 32 (32A and 32B) by operating, after the charging processing, the pump 33 (33A and 33B) so that the processing liquid L flowing through the circulation path 32 (32A and 32B) reaches the predetermined initial set flow rate F1. In the second circulation processing, after the timepoint when the processing liquid L flowing through the circulation path 32 (32A and 32B) has reached the initial set flow rate F1, the pump 33 (33A and 33B) is operated so that the processing liquid L reaches the predetermined processing set flow rate F2 for processing the substrate (wafer W). This enables an increase of the flow rate of the processing liquid L sent from the circulation path 32 back into the processing tub 21.

So far, one or more embodiments of the present disclosure have been described. However, the present disclosure is not limited to the above-described exemplary embodiments, and various changes and modifications may be made without departing from the spirit of the present disclosure.

Here, it should be noted that the above-described exemplary embodiments are illustrative in all aspects and are not anyway limiting. The above-described exemplary embodiments may be omitted, replaced and modified in various ways without departing from the scope and the spirit of claims.

According to one or more embodiments, it is possible to increase the flow rate of the processing liquid returned back into the processing tub from the circulation path.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of one or more embodiments. It shall be understood that all modifications and embodiments conceived from the meaning and scope of the claims and their equivalents are included in the scope of the inventive concept.

We claim:

1. A processing liquid supply system, comprising:
a processing tub;
a processing liquid supply configured to supply a processing liquid into the processing tub in which a substrate is immersed to be processed;
a circulation path configured to allow the processing liquid to flow out from the processing tub and return back into the processing tub;
a pump and a flowmeter provided in the circulation path; and
a controller having a processor and a memory with a computer readable program stored therein that upon execution of the computer readable program by the processor configures the controller to control each component,
wherein the controller performs:
storing the processing liquid in the processing tub by supplying the processing liquid from the processing liquid supply;
filling the circulation path with the processing liquid by operating the pump to allow the processing liquid to flow through the circulation path;
circulating the processing liquid through the circulation path by operating, after the filling of the circulation path, the pump such that the processing liquid flowing through the circulation path reaches a predetermined initial set flow rate; and
operating, after a timepoint when a measurement value of the flowmeter has reached the initial set flow rate, the pump to achieve a predetermined processing set flow rate at which the substrate is processed.

2. The processing liquid supply system of claim 1, further comprising:
a heater provided in the circulation path, and a thermometer configured to measure a temperature of the processing liquid flowing through the circulation path,
wherein the controller operates the heater to heat the processing liquid in the circulating of the processing liquid, and starts the operating of the pump to achieve the predetermined processing set flow rate when the measurement value of the flowmeter has reached the initial set flow rate and a measurement value of the thermometer has reached a predetermined temperature range.

3. The processing liquid supply system of claim 2, further comprising:
a concentration meter configured to measure a concentration of the processing liquid flowing through the circulation path,
wherein the controller operates the heater to heat the processing liquid in the circulating of the processing liquid, and starts the operating of the pump to achieve the predetermined processing set flow rate when the measurement value of the flowmeter has reached the initial set flow rate, the measurement value of the thermometer has reached the predetermined temperature range, and a measurement value of the concentration meter has reached a predetermined concentration range.

4. The processing liquid supply system of claim 1, further comprising:
a heater provided in the circulation path, and a concentration meter configured to measure a concentration of the processing liquid flowing through the circulation path,
wherein the controller operates the heater to heat the processing liquid in the circulating of the processing liquid, and starts the operating of the pump to achieve the predetermined processing set flow rate when the measurement value of the flowmeter has reached the initial set flow rate and a measurement value of the concentration meter has reached a predetermined concentration range.

5. The processing liquid supply system of claim 1,
wherein the circulation path includes multiple circulation paths,
the pump includes multiple pumps,
the flowmeter includes multiple flowmeters,
one of the multiple pumps and one of the multiple flowmeters are provided in each circulation path, and
the controller operates the pump provided in each circulation path to fill each circulation path with the processing liquid in the filling of the circulation path, and performs stopping all of the multiple pumps to stop circulation of the processing liquid in all of the multiple circulation paths between the filling of the circulation path and the circulating of the processing liquid.

6. The processing liquid supply system of claim 5,
wherein, in the circulating of the processing liquid, the controller starts the operating of the multiple pumps to achieve the predetermined processing set flow rate when measurement values of all of the multiple flowmeters have reached the initial set flow rate.

7. The processing liquid supply system of claim 1,
wherein the circulation path is branched downstream of the pump into multiple branch circulation paths,
the flowmeter includes multiple flowmeters,
the flowmeter is provided in each of the multiple branch circulation paths, and
the controller operates the pump to fill all of the multiple branch circulation paths with the processing liquid in the filling of the circulation path, and performs stopping the pump to stop circulation of the processing liquid in all of the multiple branch circulation paths between the filling of the circulation path and the circulating of the processing liquid.

8. The processing liquid supply system of claim 7,
wherein, in the circulating of the processing liquid, the controller starts the operating of the pump to achieve the predetermined processing set flow rate when measurement values of all of the multiple flowmeters have reached the initial set flow rate.

9. The processing liquid supply system of claim 1,
wherein the pump is a magnetic levitation pump configured to force-feed the processing liquid as a rotator of the magnetic levitation pump is rotated in the processing liquid while being magnetically levitated, and
the controller performs force-feeding of the processing liquid while controlling a rotation speed of the rotator based on the measurement value of the flowmeter.

10. The processing liquid supply system of claim 9,
wherein, in the filling of the circulation path, the controller operates the pump while fixing the rotation speed of the rotator to a preset rotation speed.

11. A processing liquid supply method, comprising:
storing, by supplying a processing liquid into a processing tub in which a substrate is immersed to be processed, the processing liquid in the processing tub;
filling a circulation path, which is configured to allow the processing liquid to flow out from the processing tub and return back into the processing tub, with the processing liquid by operating a pump provided in the circulation path;
circulating the processing liquid through the circulation path by operating, after the filling of the circulation path, the pump such that the processing liquid flowing through the circulation path reaches a predetermined initial set flow rate; and
operating, after a timepoint when the processing liquid flowing through the circulation path has reached the initial set flow rate, the pump to achieve a predetermined processing set flow rate at which the substrate is processed.

12. The processing liquid supply method of claim 11, further comprising
operating a heater to heat the processing liquid in the circulating of the processing liquid, and starting the operating of the pump to achieve the predetermined processing set flow rate when the measurement value of the flowmeter has reached the initial set flow rate and a measurement value of a thermometer has reached a predetermined temperature range.

13. The processing liquid supply method of claim 12, further comprising
operating the heater to heat the processing liquid in the circulating of the processing liquid, and starting the operating of the pump to achieve the predetermined processing set flow rate when the measurement value of the flowmeter has reached the initial set flow rate, the measurement value of the thermometer has reached the predetermined temperature range, and a measurement value of a concentration meter has reached a predetermined concentration range.

14. The processing liquid supply method of claim 11, further comprising
operating a heater to heat the processing liquid in the circulating of the processing liquid, and starting the operating of the pump to achieve the predetermined processing set flow rate when the measurement value of the flowmeter has reached the initial set flow rate and a measurement value of a concentration meter has reached a predetermined concentration range.

15. The processing liquid supply method of claim 11, wherein
the circulation path includes multiple circulation paths,
the pump includes multiple pumps,
the flowmeter includes multiple flowmeters,
one of the multiple pumps and one of the multiple flowmeters are provided in each circulation path, and
the method further comprises operating the pump provided in each circulation path to fill each circulation path with the processing liquid in the filling of the circulation path, and performing stopping all of the multiple pumps to stop circulation of the processing liquid in all of the multiple circulation paths between the filling of the circulation path and the circulating of the processing liquid.

16. The processing liquid supply method of claim 15, wherein, in the circulating of the processing liquid, the multiple pumps are operated to achieve the predetermined processing set flow rate when measurement values of all of the multiple flowmeters have reached the initial set flow rate.

17. The processing liquid supply method of claim 11, wherein
the circulation path is branched downstream of the pump into multiple branch circulation paths,
the flowmeter includes multiple flowmeters,
the flowmeter is provided in each of the multiple branch circulation paths, and
the method further comprises operating the pump to fill all of the multiple branch circulation paths with the processing liquid in the filling of the circulation path, and performing stopping the pump to stop circulation of the processing liquid in all of the multiple branch circulation paths between the filling of the circulation path and the circulating of the processing liquid.

18. The processing liquid supply method of claim 17, wherein, in the circulating of the processing liquid, the pump is operated to achieve the predetermined processing set flow rate when measurement values of all of the multiple flowmeters have reached the initial set flow rate.

19. The processing liquid supply method of claim 11, wherein
the pump is a magnetic levitation pump configured to force-feed the processing liquid as a rotator of the magnetic levitation pump is rotated in the processing liquid while being magnetically levitated,
the method further comprises performing force-feeding of the processing liquid while controlling a rotation speed of the rotator based on the measurement value of the flowmeter, and
in the filling of the circulation path, the pump is operated while fixing the rotation speed of the rotator to a preset rotation speed.

20. A computer-readable recording medium having stored thereon computer-executable instructions that, in response to execution, cause a processing liquid supply system to perform a processing liquid supply method as claimed in claim 11.
